(19) United States
(12) Patent Application Publication
(10) Pub. No.: US 2025/0054780 A1
(43) Pub. Date: Feb. 13, 2025

(54) CENTRAL SHAFT OF CLEANING ROLLER

(71) Applicant: CENEFOM CORP., Miaoli County (TW)

(72) Inventor: Chen-Ping HSU, Miaoli County (TW)

(21) Appl. No.: 18/636,232

(22) Filed: Apr. 15, 2024

(30) Foreign Application Priority Data
Aug. 11, 2023 (TW) 112130375

(51) Int. Cl. H01L 21/67; B08B 1/40

(52) U.S. Cl. CPC H01L 21/67046; B08B 1/40

(57) ABSTRACT

Disclosed is a central shaft of cleaning roller, including a shaft body and a hollow inner flow channel disposed in the shaft body, and a plurality of dispersed through holes fluidly-communicable with the hollow inner flow channel arranged on an outer wall of the shaft body, and a plurality of groove structures radially extending around the surface of the outer wall of the shaft body, and the groove structures have protruding end edges protruding from the surface of the outer wall. The central shaft of cleaning roller can be used to provide better adhesion for an interface between a foam material and the outer wall thereof.

### CROSS-REFERENCE TO RELATED APPLICATION

This application claims priority to Taiwan Application Serial Number 112130375, filed Aug. 11, 2023, which is herein incorporated by reference in its entirety.

### BACKGROUND

### Field of Invention

The present disclosure relates to a central shaft of a cleaning roller, and more particularly to a central shaft of a cleaning roller made of a foam brush wheel used to clean a surface of semiconductor wafers or circuit substrates.

### Description of Related Art

In order to effectively and fully remove particles or debris generated by grinding and polishing the surface of wafers or circuit substrates, the industry has currently changed from a conventional cleaning method of using a large amount of deionized water and chemical solutions to a new cleaning method that uses rollers to scrub to improve efficiency and reduce water consumption. On the premise of not scratching the surface of the object to be cleaned, the part where the cleaning roller contacts the surface of the object to be cleaned must be made of soft foam material. In order to achieve a sufficient cleaning effect, the cleaning roller needs to have a hard axis structure so that it can withstand the driving pressure, water pressure and rotational speed exerted on the cleaning roller at a certain intensity without causing the cleaning roller to deform.

However, as the size of the wafer to be cleaned increases, or the cleaning process speed increases, the pressure under the cleaning roller, the flushing water pressure, and the roller speed must also be increased. When the cleaning roller rotates at least 500 rpm, the interface adhesion strength between the heterogeneous foam material and the axial structure is often unbearable and is prone to relative sliding or distortion, causing the cleaning roller unable to adhere to the surface of the object to be cleaned, thereby affecting the cleaning effect and even damaging the object to be cleaned.

Since the cleaning solution, such as deionized water, is often input from one end of the roller axis, it is evenly dispersed through the foam material through the flow channel inside the roller axis and the communication holes distributed on the surface of the roller axis. To reach the surface of the object to be cleaned, the roller axis structure must have a specific flow channel design. However, in order to match the existing machine equipment, the overall size of the cleaning roller usually cannot be modified significantly. If a fixed structure needs to be added to secure the foam material to the roller axis structure, it may increase the difficulty of the overall design and manufacturing of the roller axis.

Therefore, there is a need for an improved cleaning roller central shaft that can increase the adhesion strength between the foam material and the axis structure interface without affecting the main structure and design of the axis. Even if high downforce and water pressure are used in the cleaning process and rotational speed, there will be no displacement between the foam material and the axis structure, causing the soft foam material to twist and deform.

### SUMMARY

The present disclosure provides a cleaning roller central shaft to deal with the needs of the prior art problems.

In one or more embodiments, a cleaning roller central shaft includes a shaft body and a hollow inner flow channel located in the shaft body, wherein the shaft body includes an outer wall surface having a plurality of through holes that are fluidly-communicable with the hollow inner flow channel. A plurality of groove structures are arranged radially and extending around the outer wall surface of the shaft body, wherein each groove structure has protruding end edges protruding from the outer wall surface of the shaft body. An angle between a radial extension direction of the groove structures and an axial direction of the shaft body ranges from −80° to 80°, and an expansion of the outer wall surface of the shaft body having the groove structures has a standard dimension ratio (Sdr) ranging from 300% to 800% and an arithmetic mean deviation (Sa) ranging from 70 μm to 300 μm.

In one or more embodiments, the protruding end edges of the groove structures have maximum heights (Sp) ranging from 500 μm to 900 μm.

In one or more embodiments, the groove structures extend in parallel arrangement or staggered arrangement.

In one or more embodiments, an intersection acute angle between two of the groove structures ranging from 10° to 45° when the groove structures extend in staggered arrangement.

In one or more embodiments, the groove structures have cross-sectional shapes of triangles, quadrilaterals or partial arcs.

In one or more embodiments, the groove structures have an opening width ranging from 0.1 mm to 0.9 mm.

In one or more embodiments, the groove structures have a depth ranging from 0.35 mm to 1.2 mm.

In one or more embodiments, the groove structures are disposed over all the outer wall surface of the shaft body.

In one or more embodiments, the hollow inner flow channel has an inner diameter ranging from 9 mm to 22 mm.

In one or more embodiments, the through holes of the shaft body have a diameter ranging from 2.5 mm to 6 mm.

In one or more embodiments, the hollow inner flow channel has a closed end and an inlet end arranged oppositely.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrate a perspective view of a cleaning roller central shaft according to one embodiment of the present disclosure;

FIG. 2 illustrate a perspective view of a cleaning roller central shaft according to another embodiment of the present disclosure;

FIGS. 3(a)-3(c) illustrate cross-sectional views of a cleaning roller central shaft according to some embodiments of the present disclosure;

FIGS. 4(a)-4(d) illustrate cleaning roller central shafts according to other embodiments of the present disclosure;

FIG. 5 illustrates an enlarged view of the cleaning roller central shaft in FIG. 2; and

FIG. 6 illustrates a cross-sectional view of the cleaning roller central shaft in FIG. 1.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The embodiments of the cleaning roller central shaft of the present invention will be described below with reference to the relevant drawings. To facilitate understanding, the same components in the following embodiments are labeled with the same symbols.

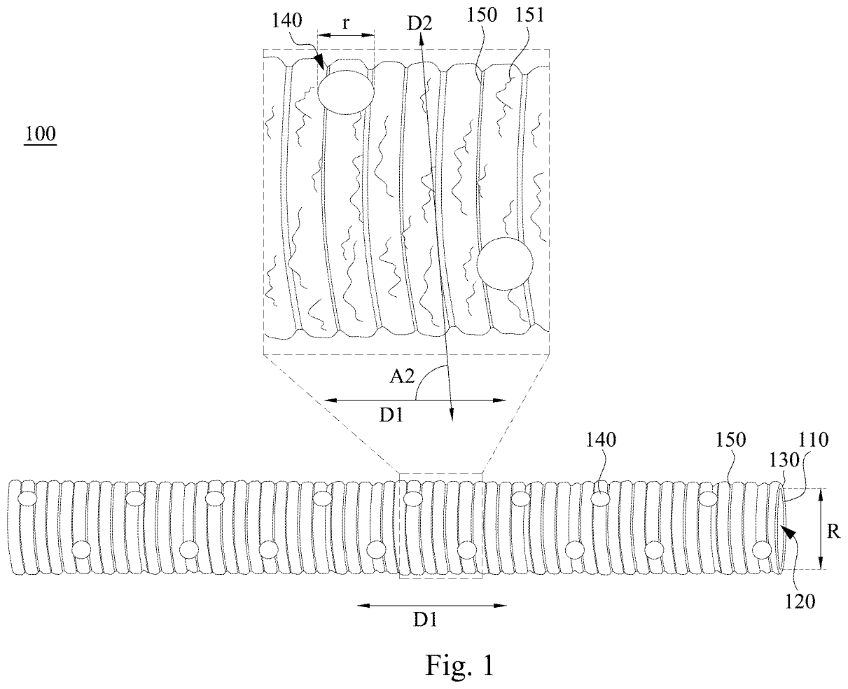

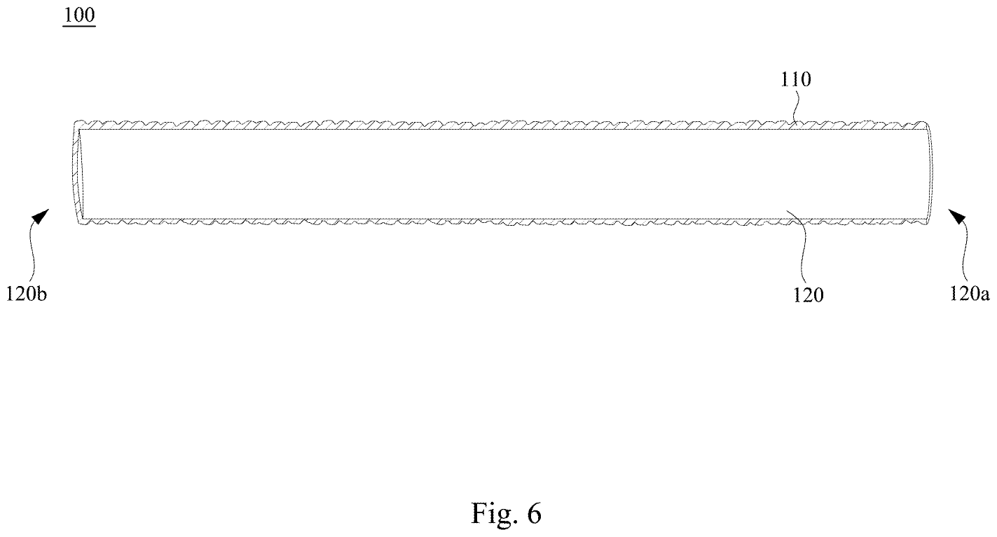

The present invention provides a cleaning roller central shaft that is a foam brush wheel used to clean semiconductor wafers or remove foreign matters on the surface of circuit substrates, etc., which can increase an interface adhesion between the foam material and the core structure. The strength ensures that even if high downforce, water pressure and rotational speed are applied during the cleaning process, the foam material and the core structure will not be displaced or the foam material will be distorted. In one embodiment (as shown in FIG. 1), the present invention provides a cleaning roller central shaft 100, which includes a shaft body 110 and a hollow inner flow channel 120. An outer wall 130 of the shaft body 110 has a plurality of dispersedly arranged through holes 140 that are fluidly-communicable with the hollow inner flow channel 120. A plurality of groove structures 150 are arranged radially and extending around the surface of the outer wall 130, and these groove structures 150 have protruding end edges 151 protruding from the surface of the outer wall 130. In some embodiments, an angle A2 between a radial extension direction D2 of the groove structures 150 and an axial direction D1 of the shaft body 110 is between −80° and 80°, and has a groove structure. In some embodiments, an expansion of the outer wall surface of the shaft body 110 having the groove structures 150 has a developed interfacial area ratio (Sdr) ranging from 300% to 800%, and the protruding end edges 151 have an arithmetic mean deviation (Sa) ranging from 70 μm to 300 μm. In some embodiments, the shaft body 110 has four rows of through holes 140 along the axial direction D1 and are equidistantly distributed in the radial direction, and a diameter (r) of the through holes 140 ranges from 2.5 mm to 6 mm. In some embodiments (as shown in FIG. 6), the hollow inner flow channel 120 has a closed end 120b and an inlet end 120a that are oppositely arranged, and an inner diameter R (as shown in FIG. 1) of the hollow inner flow channel 120 of the shaft body 110 is between 9 mm and 22 mm.

In another embodiment of the cleaning roller central shaft, a maximum height (Sp) of the protruding end edges 151 of the groove structures 150 is between 500 μm and 900 μm.

In this disclosure, “maximum height (Sp)”, “arithmetic mean deviation (Sa)” and “developed interfacial area ratio (Sdr)” are parameters generally used to evaluate surface roughness. Sp and Sa values refer to the absolute values of the maximum peak height and average height difference of a rough surface relative to the average surface of the surface. The developed interfacial area ratio (Sdr) indicates the rate of increase in surface area due to changes in surface structure where the developed interfacial area ratio (Sdr) represents the ratio of the total surface area (A1) caused by the undulations of the surface structure in the measured unit area to the projected area (A0) of the measured unit area, and is calculated by the following formula (1). The unfolded surface area ratio is measured by instruments such as laser conjugate focus microscope, three-dimensional white light interferometer or scanning electron microscope that can obtain the surface topography in accordance with the method specified in ISO25178.

Sdr(%)=[(A1/A0)−1]×100% formula (1).

In the present disclosure, Sp and Sa values refer respectively to the maximum peak height and the arithmetic mean height of the protruding end edge formed by the groove structures relative to the outer wall surface of the shaft body. The developed interfacial area ratio (Sdr) indicates the rate of increase in surface area after the groove structure is formed, i.e., the surface area of the outer wall surface of the shaft body is increased due to the groove structure and the protruding end edge.

In the present disclosure, the groove structures 150 can be formed on the outer wall 130 of the shaft body 110 by using a structural molding method such as cutting tools or laser engraving. These groove structures 150 can be formed by adjusting the cutting depth or angle while using engraving tools, or by adjusting laser energy, angle, moving speed, focus control, etc. while using engraving laser such that the protruding end edges 151 protruding from the surface of the outer wall 130 is simultaneously formed.

When the cleaning roller central shaft 100 of the present invention is combined with a foam material (not shown in the figure), the foam material can penetrate into the groove structures 150. Since the outer wall 130 of the shaft body 110 has the groove structures 150 and the protruding end edges 151 protruding from the surface of the outer wall 130, the surface area of the shaft body is greatly increased by these micro-structures to enhance a contact area between the foam material and the cleaning roller central shaft, and the contact area strengthens the interface effective adhesion between the foam material and the cleaning roller central shaft 100, so that the soft foam material does not cause defects of uneven local stress and distortion due to factors such as increased roller pressure, water pressure and rotation speed.

Since a radial extension direction D2 of the groove structures 150 and the axial direction D1 of the shaft body 110 have an included angle between −80° and 80°, the groove structures 150 can provide a force component for the cleaning roller to fix the foam material during the rotation of the cleaning roller. And when the maximum height (Sp) of the protruding end edges 151 of the groove structures 150 is between 500 μm and 900 μm, and the arithmetic mean deviation (Sa) is between 70 μm and 300 μm, the shaft body 110 is equipped with a force acting in a tangential direction on the surface of the outer wall 130, thereby preventing the foam material from sliding along the rotation direction.

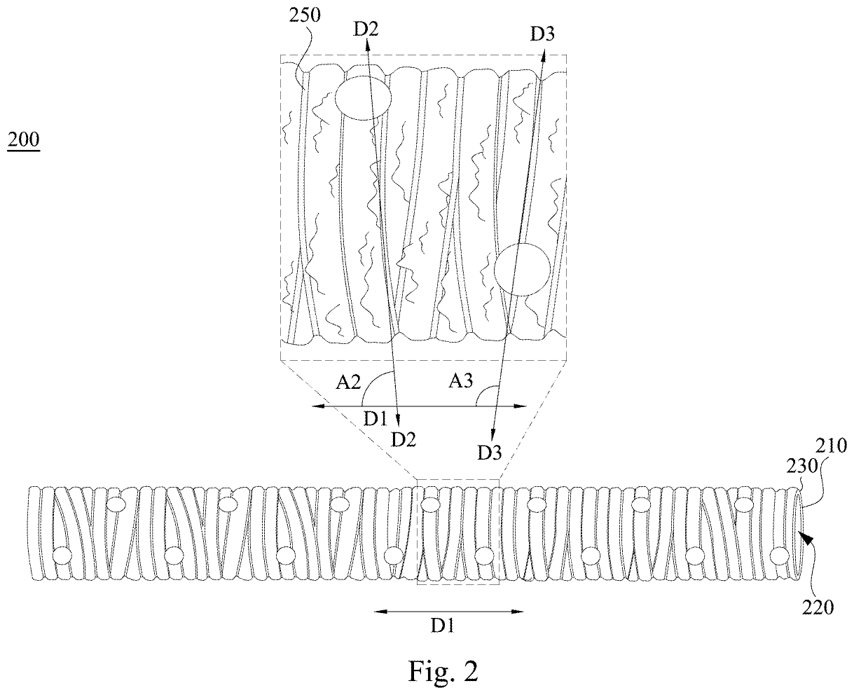

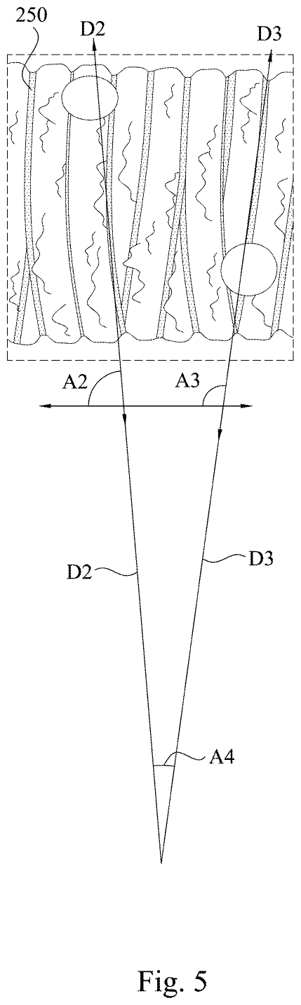

Reference is made to FIGS. 2 and 5, which illustrates a perspective view of a cleaning roller central shaft 200 and its enlarged view according to another embodiment of the present disclosure. The plurality of groove structures 250 on the surface of the outer wall 230 of the shaft body 210 of the cleaning roller central shaft 200 have the same parallel arrangement of radial extension directions, or a staggered arrangement of multiple different radial extension directions, etc. An included angle with the axial direction D1 must be between −80° and 80°. For example, in FIG. 2, the included angles (A2, A3) between the radial extension directions (D2, D3) and the axial direction D1 are both between −80° and 80°. When the groove structures 250 are arranged in a staggered manner, an intersection acute angle (A4) between the radial extension directions D2 and D3 is between 10° and 45°, preferably between 20° and 30°. On the surface of the outer wall 230 of the shaft body, through the staggered design of the groove structures 250, the cleaning roller central shaft 200 can further provide better anchoring force when combined with the foam material (not shown in the figure), so that the shaft body 210 are bonded with foam materials more closely.

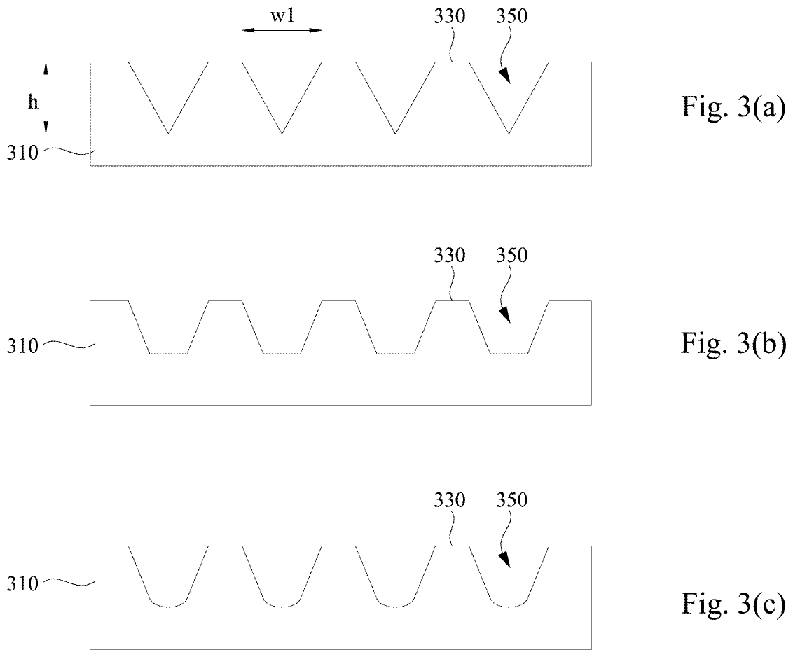

FIGS. 3(a) to 3(c) are schematic cross-sectional views illustrating the extending direction of the groove structures of the cleaning roller central shaft of the present invention. The protruding end edges of the groove structures 350 are not shown in the figures. The cleaning roller central shaft of the present invention provides a groove structure 350 on the outer wall 330 of the shaft body 310. A bottom shape of the cross-section of the groove structure 350 is not particularly limited. For example, it can be a triangle, a quadrilateral or a partial arc, etc. It is set according to the method of forming the groove structure 350, such as a cutting tool or laser engraving and other structural forming methods. In an embodiment of the present invention, an opening width (w1) of the groove structures 350 is between 0.1 mm and 0.9 mm to facilitate the penetration and adhesion of the foam material (not shown in the figure). Furthermore, a depth (h) of the groove structures 350 is between 0.35 mm and 1.2 mm. Since the depth (h) of the groove structures 350 is much smaller than a conventional wall thickness of the shaft body 310, it does not affect an overall strength of the shaft body 310.

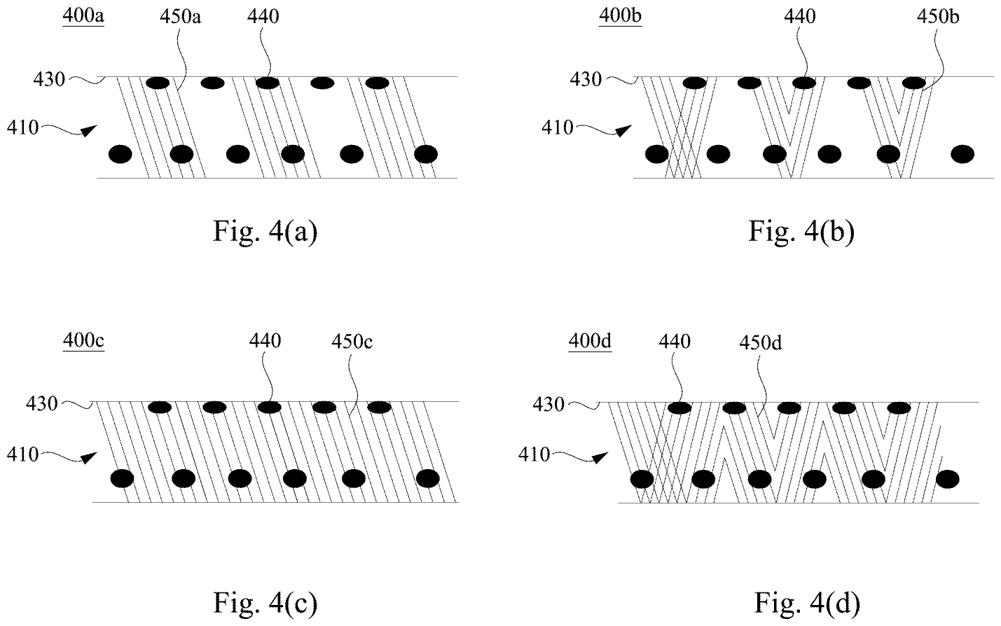

FIGS. 4(a) to 4(d) are schematic diagrams illustrating the groove structures of the cleaning roller central shaft of the present invention. Referring to FIGS. 4(a) and 4(b), it is shown that a plurality of groove structures 450a and 450b on the cleaning roller central shafts 400a and 400b are evenly and periodically spaced and arranged in parallel or staggered arrangements on the surface of outer wall 430 of the shaft body 410. Referring to FIGS. 4(c) and 4(d), which show that the plurality of groove structures 450c and 450d of the cleaning roller central shaft 400c and 400d are arranged in parallel or staggered to completely cover the surface of the outer wall 430 of the shaft body 410. The groove structures 450a to 450d on the outer wall 430 of the shaft body 410 can provide a good and uniform adhesion interface between the outer wall 430 of the shaft body 410 and the foam material, so as to tightly combine the foam material and prevent relative sliding and distortion.

In addition, when an outer edge of the through hole 450 on the outer wall 430 of the shaft body 410 is fluidly-communicable with the groove structures 450a to 450d, the cleaning liquid flowing out of the through hole 440 from the hollow inner flow channel can partially flow to the groove structure after. The groove structures 450a to 450d are designed to cause the cleaning liquid flown more quickly from the side to the outer wall surface of the cleaning roller central shaft under the rotation of the cleaning roller central shaft, thereby achieving a better overall uniform dispersion effect.

In another embodiment of the cleaning roller central shaft of the present invention, the hollow inner flow channel has a closed end and an inlet end arranged oppositely, and an inner diameter of the hollow inner flow channel in the shaft body is between 9 mm and 22 mm room. Furthermore, the distribution quantity, arrangement and hole diameter of the through holes on the shaft body of the cleaning roller central shaft of the present invention can be designed according to the actual application requirements. In some embodiments of the cleaning roller central shaft of the present invention, the through holes are equidistantly distributed in the radial direction and arranged along the axial direction of the shaft body. In some embodiments of the present invention, the shaft body has four rows of through holes along the axial direction, equidistantly distributed in the radial direction, and the hole diameter is between 2.5 mm and 6 mm.

In sum, the silicon carbide wafer manufacturing method disclosed herein utilizes epitaxy technology to grow a thicker, high-quality silicon carbide epitaxial layer, and uses wafer separation technology to implant a high dose of H+ or He+ into the silicon carbide wafer by an ion implantation process. The silicon carbide wafer is bonded to the temporary substrate, and the temporary substrate with the silicon carbide epitaxial layer is peeled off through heating. After the silicon carbide epitaxial layer on the temporary substrate is peeled off, it is transferred to a permanent silicon carbide substrate. The silicon carbide substrate and the original silicon carbide wafer are processed to remove the damaged layer and restore the surface of the epitaxial layer to a flat state by CMP processes. Finally, two silicon carbide wafers with high-quality epitaxial layers can be obtained.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A cleaning roller central shaft comprising:
a shaft body and a hollow inner flow channel located in the shaft body, wherein the shaft body includes an outer wall surface having a plurality of through holes that are fluidly-communicable with the hollow inner flow channel; and
a plurality of groove structures arranged radially and extending around the outer wall surface of the shaft body, wherein each groove structure has protruding end edges protruding from the outer wall surface of the shaft body,
wherein an angle between a radial extension direction of the groove structures and an axial direction of the shaft body ranges from −80° to 80°, and an expansion of the outer wall surface of the shaft body having the groove structures has a developed interfacial area ratio (Sdr) ranging from 300% to 800% and an arithmetic mean deviation (Sa) ranging from 70 μm to 300 μm.

2. The cleaning roller central shaft of claim 1, wherein the protruding end edges of the groove structures have maximum heights (Sp) ranging from 500 μm to 900 μm.

3. The cleaning roller central shaft of claim 1, wherein the groove structures extend in parallel arrangement or staggered arrangement.

4. The cleaning roller central shaft of claim 3, wherein an intersection acute angle between two of the groove structures ranging from 10° to 45° when the groove structures extend in staggered arrangement.

5. The cleaning roller central shaft of claim 1, wherein the groove structures have cross-sectional shapes of triangles, quadrilaterals or partial arcs.

6. The cleaning roller central shaft of claim 5, wherein the groove structures have an opening width ranging from 0.1 mm to 0.9 mm.

7. The cleaning roller central shaft of claim 1, wherein the groove structures have a depth ranging from 0.35 mm to 1.2 mm.

8. The cleaning roller central shaft of claim 1, wherein the groove structures are disposed over all the outer wall surface of the shaft body.

9. The cleaning roller central shaft of claim 1, wherein the hollow inner flow channel has an inner diameter ranging from 9 mm to 22 mm.

10. The cleaning roller central shaft of claim 1, wherein the through holes of the shaft body have a diameter ranging from 2.5 mm to 6 mm.

11. The cleaning roller central shaft of claim 1, wherein the hollow inner flow channel has a closed end and an inlet end arranged oppositely.
